(19) United States
(12) Patent Application Publication
(10) Pub. No.: US 2015/0118415 A1
(43) Pub. Date: Apr. 30, 2015

(54) PLASMA PROCESSING APPARATUS AND METHOD OF PERFORMING PLASMA PROCESS

(71) Applicant: Tokyo Electron Limited, Tokyo (JP)

(72) Inventors: Hitoshi KATO, Iwate (JP); Shigehiro MIURA, Iwate (JP)

(21) Appl. No.: 14/514,537

(22) Filed: Oct. 15, 2014

(30) Foreign Application Priority Data
Oct. 25, 2013 (JP) 2013-222202

(51) Int. Cl. C23C 16/50; C23C 16/455; C23C 16/448; C23C 16/458

(52) U.S. Cl. CPC C23C 16/50; C23C 16/4584; C23C 16/45563; C23C 16/4488
USPC 427/569; 118/723 R

(57) ABSTRACT

A plasma processing apparatus for processing a substrate includes a turntable for orbitally revolving a substrate mounting area; a nozzle portion facing the substrate mounting area and having gas discharge ports for generating plasma; an antenna including a linear portion extending to cover a substrate passage area on a downstream side relative to the nozzle portion and a separated portion, wound around a vertical axis, and generating induction plasma in a process area to which the gas is supplied; a Faraday shield including a conductive plate provided between the antenna and the process area to cut off an electric field, and slits formed to orthogonally cross the antenna and cause a magnetic field to pass therethrough, wherein the slits are formed on aside lower than the linear portion and a portion of the conductive plate without the slits is positioned on a side lower than a curved portion.

### CROSS-REFERENCE TO RELATED APPLICATIONS

This patent application is based upon and claims the benefit of priority of Japanese Patent Application No. 2013-222202 filed on Oct. 25, 2013, the entire contents of which are incorporated herein by reference.

### BACKGROUND OF THE INVENTION

1. Field of the Invention

The present invention relates to a plasma processing apparatus and a method of performing plasma process.

2. Description of the Related Art

Japanese Laid-open Patent Publication No. 2011-151343 discloses a semibatch type apparatus for providing a plasma process to a substrate (hereinafter, referred to as a “wafer”) such as a semiconductor wafer. Specifically, Japanese Laid-open Patent Publication No. 2011-151343 discloses that five wafers are arranged in a peripheral direction of the turntable on the turntable and a plasma generating portion such as a pair of opposing electrodes or an antenna is arranged so as to face an orbit of the wafer moved (orbitally revolved) by the turntable. According to Japanese Laid-open Patent Publication No. 2011-151343, multiple plasma generating portions are arranged, and a degree of the plasma process on a surface of the wafer is adjusted by mutually changing the lengths of the multiple plasma generating portions.

Japanese Laid-open Patent Publication No. 2013-45903 discloses a technique by which an antenna is arranged at a position hermetically separated from an ambient atmosphere inside the vacuum chamber and a Faraday shield having slits formed therein is provided between the antenna and the wafer. Electric field components of an electromagnetic field generated by the antenna are cut off, and magnetic field components generate plasma.

However, these Japanese Laid-open Patent Publication No. 2011-151343 and Japanese Laid-open Patent Publication No. 2013-45903 do not study a technique of uniformizing a distribution of the plasma generated on the lower side of arbitrary one of multiple antennas.

### SUMMARY OF THE INVENTION

The present invention is provided in consideration of the above situation, and the object of the present invention is to provide a plasma processing apparatus that can perform a process of achieving a high uniformity on a surface of a substrate in providing a plasma process to the substrate and a method of performing the plasma process.

According to an aspect of the invention, there is provided a plasma processing apparatus performing a plasma process for a substrate inside a vacuum chamber including a turntable for orbitally revolving a substrate mounting area, on which a substrate is mounted; a nozzle portion that faces the substrate mounting area and has gas discharge ports for discharging a gas for generating plasma linearly arranged from a side of an outer periphery to a side of a center portion; an antenna that includes a linear portion extending so as to cover a substrate passage area on a downstream side in a rotational direction of the turntable relative to the nozzle portion and a separated portion positioned separated from the linear portion in a plan view of the antenna, is wound around an axis vertically extending in up and down directions, and generates induction plasma in a process area to which the gas is supplied; a Faraday shield including a conductive plate provided between the antenna and the process area so as to hermetically separated from the process area and to cut off an electric field of an electromagnetic field, and a group of slits formed so as to orthogonally cross the antenna and cause a magnetic field of the electromagnetic field to pass through the slits, wherein the group of slits is formed on at least a side lower than the linear portion and a portion of the conductive plate without the group of slits is positioned on aside lower than a curved portion, at which the antenna curves from an end of the linear portion.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a longitudinal cross-sectional view of an exemplary plasma processing apparatus according to an embodiment of the present invention;

FIG. 2 is a cross-sectional plan view of the plasma processing apparatus;

FIG. 3 is a cross-sectional plan view of the plasma processing apparatus;

FIG. 4 is a longitudinal cross-sectional view of the plasma processing apparatus;

FIG. 5 is an exploded perspective view of the plasma processing apparatus;

FIG. 6 is a plan view of the antenna;

FIG. 7 is a plan view illustrating a positional relationship between the antenna and the wafer;

FIG. 8 is a perspective view of a casing, in which the antenna is accommodated, viewed from a lower side;

FIG. 9 is a plan view schematically illustrating a locus of plasma covering a wafer;

FIG. 10 is a longitudinal cross-sectional view of the casing inside which the plasma is retained;

FIG. 11 is a view schematically illustrating a state where the plasma and a plasma generating gas changes along a passage of time;

FIG. 12 is a longitudinal cross-sectional view of another exemplary plasma processing apparatus; and

FIG. 13 is a characteristic diagram illustrating results of simulation obtained by an embodiment of the present invention.

### DETAILED DESCRIPTION OF EMBODIMENTS

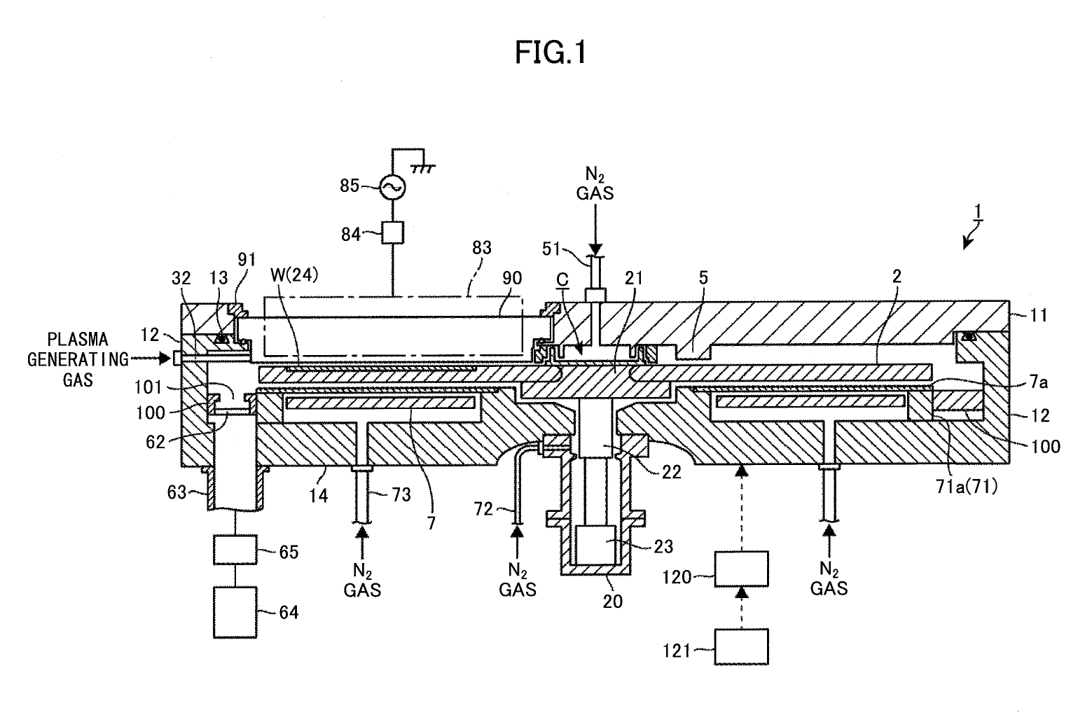

A description is given below, with reference to the FIG. 1 through FIG. 13 of embodiments of the present invention.

In the embodiments described below, the reference symbols typically designate as follows:
W: wafer;
1: vacuum chamber;
2: turntable;
P1: adsorption area;
P2: reaction area;
31, 32, 34: gas nozzle;
83: antenna;
95: Faraday shield; and
97: slit.

Referring to 1 to 8, an exemplary plasma processing apparatus of an embodiment is described. As illustrated in FIGS. 1 to 3, the plasma processing apparatus includes a vacuum chamber 1 whose plan view is substantially circular and a turntable 2 having a rotational center at a center of the vacuum chamber 1, and is structured to perform a film deposition process provided to the wafer W using plasma. In this apparatus, portions of the plasma processing apparatus are structured as described below so that a process achieving high uniformity through the surface of the wafer W can be performed by generating the plasma.

The vacuum chamber 11 includes a ceiling plate 11 and a chamber body 12. In the vacuum chamber 11, a nitrogen (N₂) gas is supplied as a separation gas through a separation gas supplying pipe 51 that is connected at a center portion on the upper side of the ceiling plate 11. As illustrated in FIG. 1, a heater unit 7 as a heating mechanism is provided on the lower side of the turntable 2. The heater unit 7 heats the wafers W through the turntable 2 so that the wafers W are heated to be, for example, 300°. Referring to FIG. 1, a reference symbol 13 designates an ◯ ring. Further, referring to FIG. 1, a reference symbol 71a designates a cover member of the heater unit 7, a reference symbol 7a designates a lid for covering the heater unit 7, and reference symbols 72 and 73 designate purge gas supplying pipes.

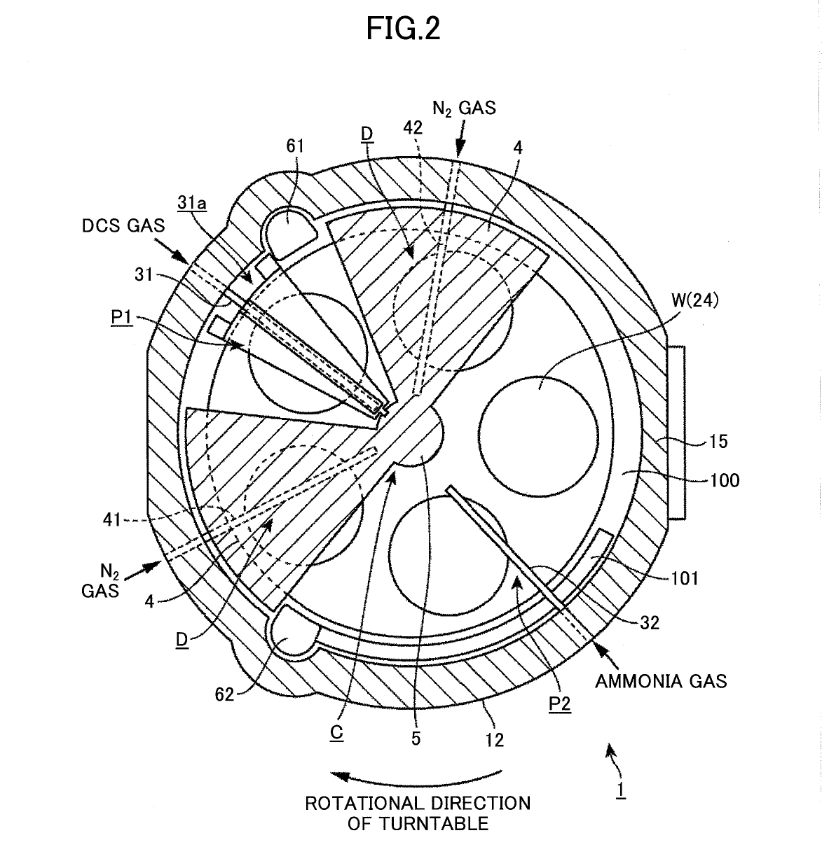

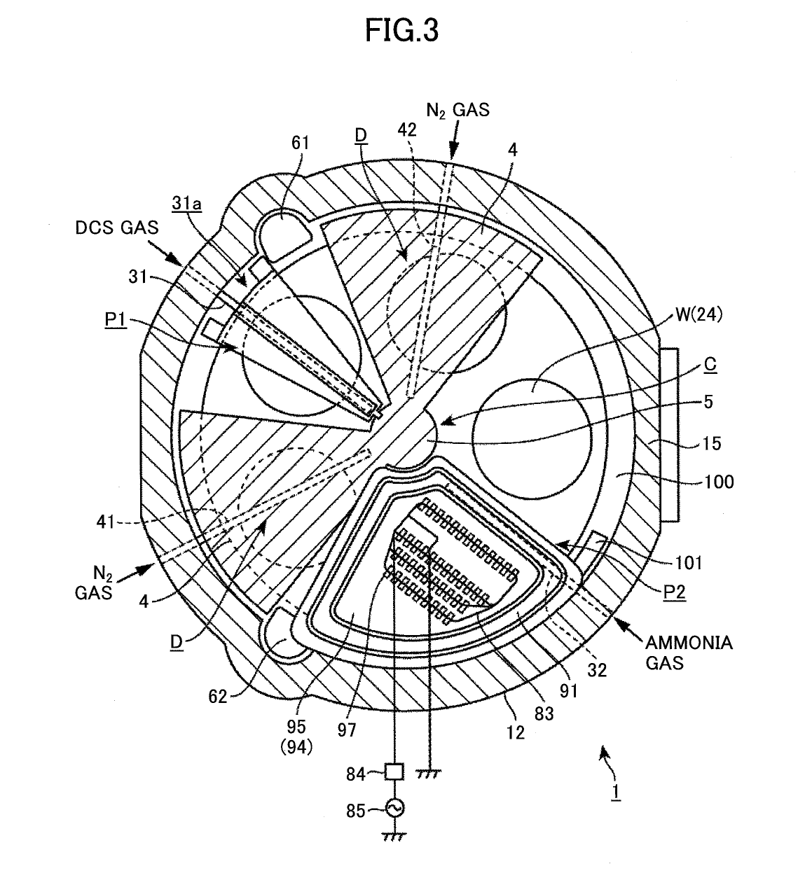

A core portion 21 having a substantially cylindrical shape is attached to a center portion of the turntable 2, and a rotational shaft 22 is connected onto the lower surface of the core portion 21. The turntable 2 can be freely rotatable around a vertical axis by the rotational shaft 22 in, for example, a clockwise direction. Referring to FIGS. 2 and 3, multiple circular concave portions 24 are provided on the surface of the turntable 2 as substrate mounting areas to receive and hold the wafers W by dropping the wafers thereinto. The multiple concave portions 24 are located at, for example, five positions along a rotational direction (a peripheral direction) of the turntable 2. Referring to FIG. 1, a reference symbol 23 designates a driving mechanism (a rotation mechanism), and a reference symbol 20 designates a case body.

At a position of a passage area of the concave portions 24, four nozzles 31, 32, 41, and 42 made of, for example, quartz are radially arranged while mutually interposing intervals in the peripheral direction of the vacuum chamber 1. For example, these nozzles 31, 32, 41, and 42 are attached to the vacuum chamber 1 so as to horizontally extend from an outer peripheral wall toward the center area C while facing the wafers W. In this example, a plasma generating gas nozzle 32, a separation gas nozzle 41, a process gas nozzle 31, and a separation gas nozzle 42 are arranged in this order in a clockwise direction from the transfer opening 15 (described later). The gas nozzle 31 and the plasma generating gas nozzle 32 respectively form a process gas supplying portion and a nozzle portion. The separation gas nozzles 41 and 42 function as a separation gas supplying portion. FIG. 2 illustrates a state where an antenna 83 and a casing 90 are removed so that the plasma generating gas 32 can be observed. FIG. 3 illustrates a state where the antenna 83 and the casing are attached.

The nozzles 31, 32, 41, and 42 are connected to corresponding gas supplying sources (not illustrated) through flow rate adjusting valves. Said differently, the process gas nozzle 31 is connected to a gas supplying source for supplying a process gas containing silicon (Si) such as a dichlorosilane (DSC) gas. The plasma generating gas nozzle 32 is connected to a gas supplying source for supplying the plasma generating gas such as an ammonia (NH3) gas. The separation gas nozzles 41 and 42 are connected to corresponding gas supplying sources for supplying the separation gas, namely a nitrogen gas. Gas discharging ports 33 are formed on the lower surface sides of the gas nozzles 31, 32, 34, 41, and 42. The gas discharging ports 33 are arranged at, for example, an equal interval and at multiple locations along a radius direction of the turntable 2. The gas discharge ports 33 of the gas nozzles 31, 41, and 42 are formed on lower surfaces of the gas nozzles 31, 41, and 42. The gas discharge ports 33 of the plasma gas nozzle 32 are formed on a side surface of the plasma gas nozzle 32 on an upstream side in the rotational direction of the turntable 2. Reference symbol 31a in FIGS. 2 and 3 designates a nozzle cover covering an upper side of the process gas nozzle 31.

An area lower than the process gas nozzle 31 is an adsorption area P1 for causing a component of the process gas to be adhered to the wafer W. Further, an area on a lower side of the plasma generating gas nozzle 32 (an area lower than the casing 90, described below) is a reaction area (a process area) P2 for causing the component of the process gas adsorbing onto the wafer to react with plasma of the plasma generating gas. The separation gas nozzles 41 and 42 are provided to form a separation area D for separating the areas P1 and P2. Referring to FIG. 2 and FIG. 3, the ceiling plate 11 of the vacuum chamber 1 has a convex portion 4 substantially in a sector-like shape. The separation gas nozzles 41 and 42 are accommodated in the convex portion 4.

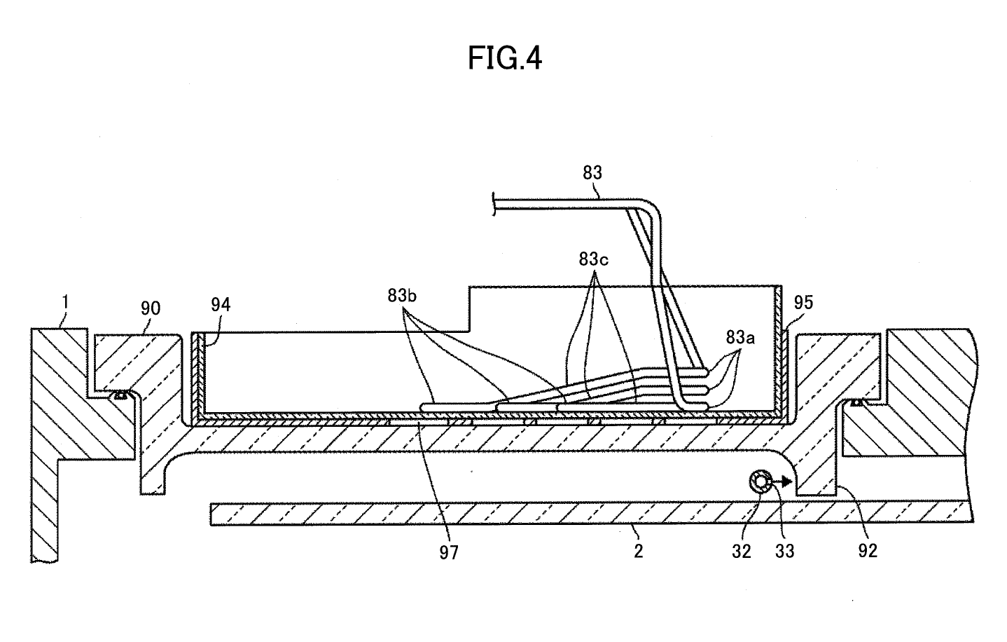

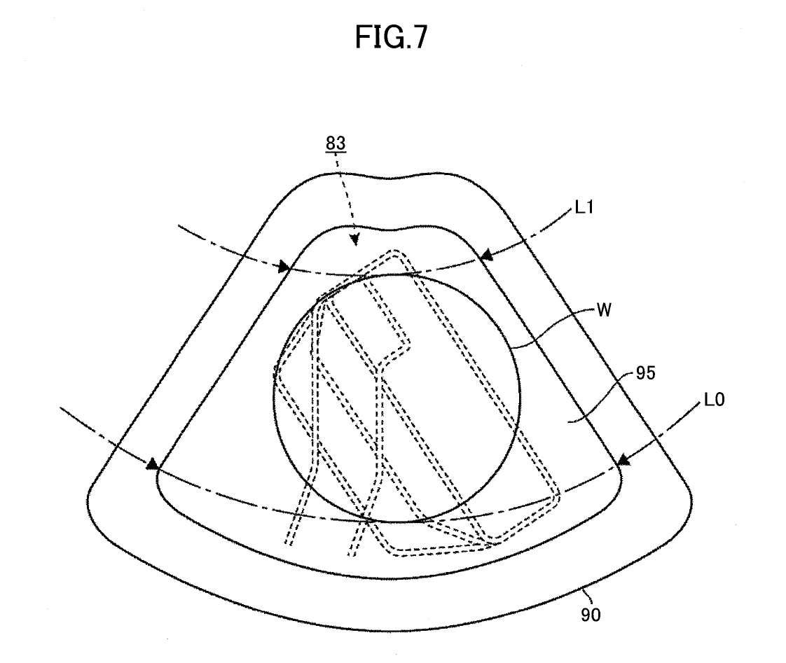

Next, a structure of generating induction plasma from the plasma generating gas is described in detail. Referring to FIGS. 3 and 4, the antenna 83 formed by winding a metallic wire in a coil-like shape is arranged on a side upper than the plasma generating gas nozzle 32. Referring to FIG. 7, this antenna 83 is arranged so as to bridge the passage area of the wafer W from a side of a center portion of the turntable through a side of an outer circumferential portion of the turntable in a plan view. Further, the antenna 83 is wound by multiple turns, in this example three turns, around an axis (a vertical axis) extending vertically from the surface of the turntable 2. Said differently, in the antenna 83, circumferential portions of the antenna 83 are vertically laminated in three stages (three turns), and ends of each circumferential portion are connected in series. The three stages of the antenna 83 are connected through a matching box 84 with a high frequency power source 85 so as to be commonly connected with the high frequency power source 85. In this example, the frequency and the output power of the high frequency power source 85 are, for example, 13.56 MHz and 5000 W, respectively.

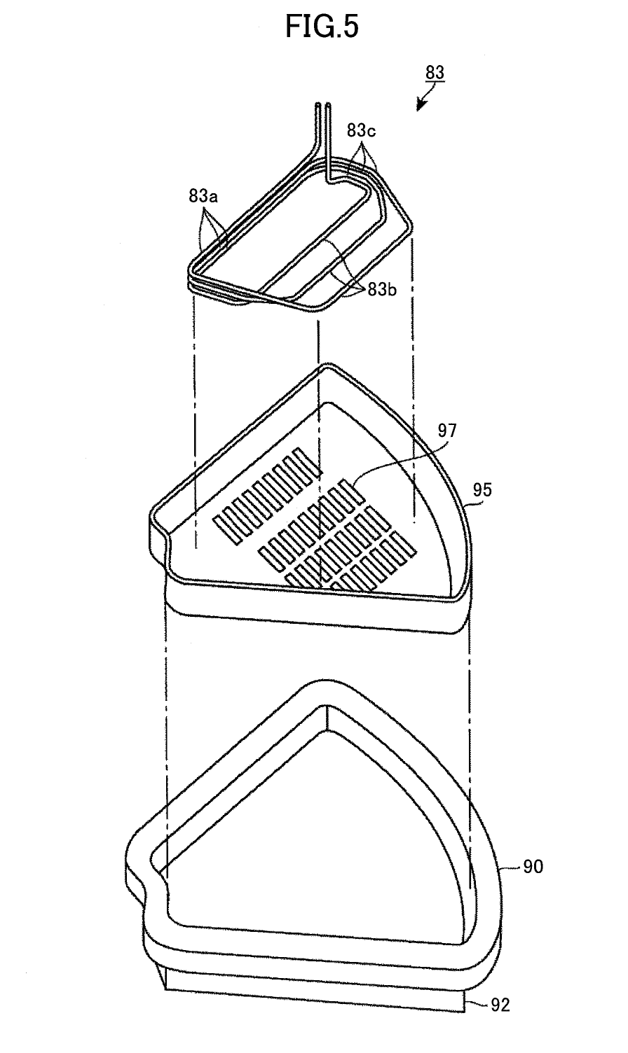

Referring to FIGS. 5 and 7, the lower stage of the three stages of the circumferential portions of the antenna 83 is formed so as to surround a substantially oblong (rectangular) area extending along a radius direction of the turntable 2. Therefore, in the lower stage of the circumferential portion, portions on the upstream and downstream sides in the rotational direction of the turntable 2 and portions on the center side and the peripheral side of the turntable 2 are formed to be linear. Specifically, the portions on the upstream and downstream sides in the rotational direction of the turntable 2 are formed along the radius direction of the turntable, said differently, along the length direction of the plasma generating gas nozzle 32. Further, portions on the center side and the outer peripheral side of the lower stage of the circumferential portion are formed to go along a tangential direction of the turntable 2.

Here, a portion of the lower stage of the circumferential portion formed along the length direction of the plasma generating gas nozzle 32 on the upstream side of the rotational direction of the turntable are called a linear portion 83a, and a portion of the lower stage of the circumferential portion formed to be linear at a position opposite to the linear portion 83a is called an opposite portion 83b. A residual portion of the lower stage of the circumferential portion extending from ends and other ends of the linear portion 83a and the opposite portion 83b is called a curved portion 83c. The linear portion 83a of the lower stage of the circumferential portion is arranged at a position slightly separated on the downstream side of the turntable 2 relative to the plasma generating gas nozzle 32 in a plan view.

In the antenna 83, the middle stage of the circumferential portion is laminated above the lower stage of the circumferential portion. The middle stage of the circumferential portion is formed to be substantially the same shape as the lower stage of the circumferential portion and includes a linear portion 83a, an opposite portion 83b, and a curved portion 83c. The linear portion 83a of the middle stage of the circumferential portion is laminated on a side of the upper layer of the linear portion 83a of the lower stage of the circumferential portion. On the other hand, the opposite portion 83b of the middle stage of the circumferential portion is arranged at a position apart from the opposite portion 83b of the lower stage of the circumferential portion on a downstream side in the rotational direction of the turntable 2. In the middle stage of the circumferential portion, the opposite portion 83b is linearly arranged at a position close to the wafer W (a position where an insulating member 94 described later touches) on the turntable 2 so as to go along the length direction of the plasma generating gas nozzle 32.

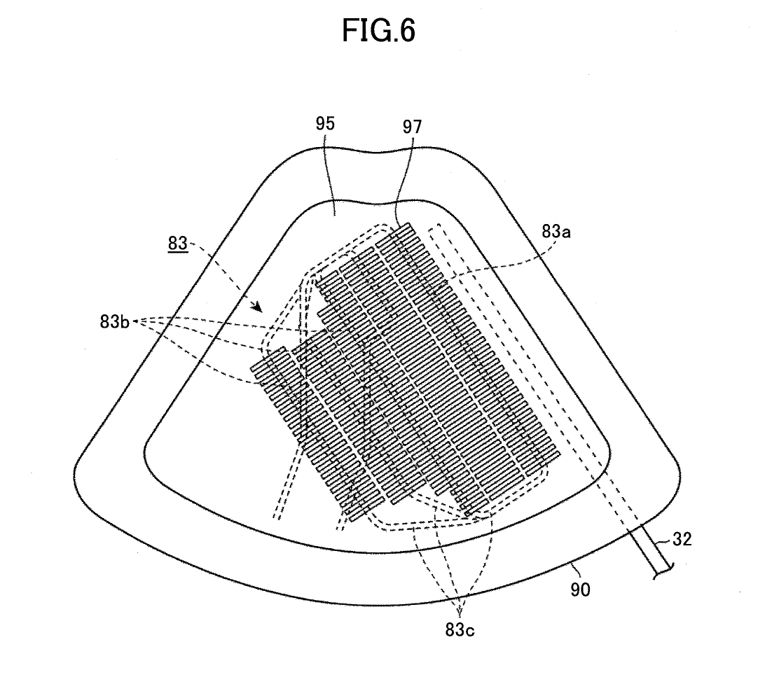

In the antenna 83, the upper stage of the circumferential portion is laminated above the middle stage of the circumferential portion. The upper stage of the circumferential portion includes a linear portion 83a, an opposite portion 83b, and a curved portion 83c. The linear portion 83a of the circumferential portion is laminated on the linear portions 83a on the side of the lower stage. The opposite portion 83b of the upper stage of the circumferential portion is arranged apart from the opposite portion 83b of the middle stage of the circumferential portion on the downstream side of the rotational direction of the turntable 2 and is arranged along the length direction of the plasma generating gas nozzle 32 so as to be linear at a position close to the wafer W on the turntable 2. Referring to FIGS. 6 and 7, the antenna is indicated by a broken line. Referring to FIG. 7, the wafer W is indicated by a solid line.

Referring to FIG. 4, at a position adjacent to the downstream side in the rotational direction of the turntable 2 relative to the plasma generating gas nozzle 32, three stages of the linear portions 83a are vertically laminated. At a position apart from the above position adjacent to the downstream side, the three opposite portions 83b are arranged side by side. As described below, plasma of the ammonia gas (the plasma generating gas) is quickly generated at the position in the vicinity of the plasma generating gas nozzle 32. At the position apart from the position in the vicinity of the plasma generating gas nozzle 32, the inactivated ammonia gas is changed to plasma again.

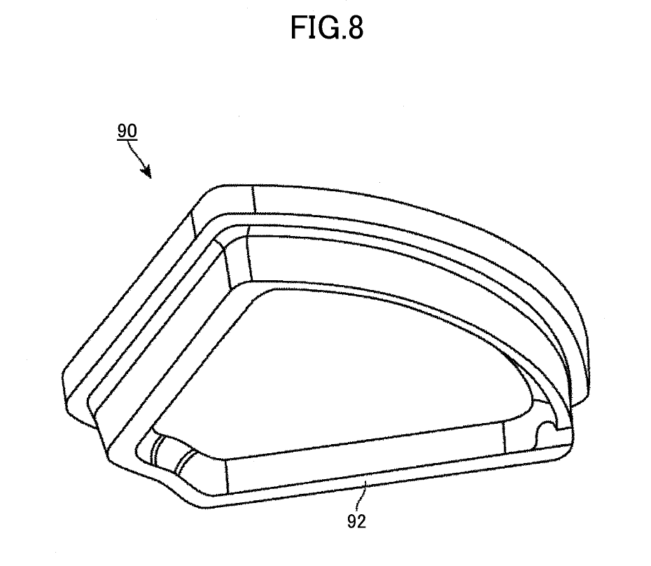

The antenna 83 is arranged so as to be hermetically separated from the inner area of the vacuum chamber 1. Said differently, the ceiling plate 11 has an opening substantially in a sector-like shape in its plan view on the upper side of the second process gas nozzle 32 and is hermetically sealed by the casing 90 made of, for example, quartz. As illustrated in FIGS. 5 and 8, the upper peripheral edge portion of the casing 90 horizontally extends like a flange in the peripheral direction of the casing 90. Further, the central portion of the casing 90 is recessed toward the inner area of the vacuum chamber 1. The antenna 83 is accommodated inside the casing 90. The casing 90 is fixed to the ceiling plate 11 by a fixing member 91. The fixing member 91 is omitted from illustration except for FIGS. 1 and 2.

The lower surface of the casing 90 has a wall portion 92 for preventing a nitrogen gas or the like from intruding into the lower area of the casing 90. Referring to FIGS. 1 and 8, the outer edge portion vertically protrudes onto the lower side (a side of the turntable 2) along its periphery to form the wall portion 92. Referring to FIGS. 5 and 8, the upstream and downstream sides of the wall portion 92 in the rotational direction of the turntable 2 extend radially from the center of the turntable 2 and are separated so as to be apart each other in the peripheral direction of the turntable 2. Referring to FIG. 4, the wall portion 92 is positioned on an outside of an outer periphery of the turntable 2 on outer peripheral side of the turntable 2. When the area surrounded by an inner peripheral surface of the wall portion 92, a lower surface of the casing, and an upper surface of the turntable is called a “reaction area P2”, the reaction area P2 is separated by the wall portion 92 so as to be shaped like a sector. The above-described plasma generating gas nozzle 32 is arranged in the vicinity of the wall portion 92 at an end on the upstream side in the rotational direction of the turntable 2 inside the reaction area P2.

Said differently, referring to FIG. 8, a lower end of the wall portion 92 is formed as follows. A portion, into which the plasma generating gas nozzle 32 is inserted, upward curves along an outer peripheral surface of the plasma generating gas nozzle 32. Portions of the lower end of the wall portion 92 other than the above portion are arranged so as to have a height close to the turntable along the peripheral direction. Referring to FIG. 4, the gas discharge ports 33 of the plasma generating gas nozzle 32 are formed to horizontally face the upstream side of the wall portion 92 that surround the reaction area P2 in the rotational direction of the turntable 2.

As described above, the wafer W orbitally revolves around by the turntable 2 and passes the areas P1 and P2 on a side lower than the nozzles 31 and 32. Therefore, on the turntable 2, the speed (the angular speed) of the end on the rotational center side of the wafer W passing through the areas P1 and P2 is different from the speed (the angular speed) of the end on the outer peripheral side of the wafer W passing through the areas P1 and P2 differ. Specifically, in a case where the diameter of the wafer W is 300 mm (12 inch size), the speed of the end on the rotational center side is one third of the speed of the end on the outer periphery side.

Said differently, provided that the distance between the rotational center of the turntable 2 and the end of the wafer on the rotational center side is s, the dimension DI of the circumference through which the end of the wafer W on the rotational center side passes is (2×π×s). Meanwhile, the dimension DO of the circumference through which the end of the wafer W on the outer peripheral side passes is (2×π×(s+300)). By the rotation of the turntable 2, the wafer W moves through the dimensions DI and DO within the same time. Therefore, provided that the speeds of the end on the rotational center side and on the outer peripheral side of the wafer W on the turntable are VI and VO, respectively, a ratio R (VI/VO) of the speeds VI and VO is (s/(s+300)). In a case where the distance s is 150 mm, the ratio R becomes 1/3.

Therefore, in a case where plasma which does not have very high reactivity with a component of the DSC gas adsorbing on the wafer W such as the plasma of the ammonia gas, a thin film (the reaction product) on the outer peripheral side becomes thinner than on the center side if the ammonia gas is changed to the plasma in the vicinity of the plasma generating gas nozzle 32.

According to the present invention, the shape of the wall portion 92 is adjusted to perform a uniform plasma process for the wafer W. Specifically, as illustrated in FIG. 7, provided that the length of a locus through which the end on the rotational center side of the wafer W on the turntable 2 passes in the reaction area P2 is indicated by LI, and the length of a locus through which the end on the outer peripheral side of the wafer W on the turntable 2 passes in the reaction area P2 is indicated by LO, a ratio (LI/LO) of LI relative to LO is 1/3. The shape of the wall portion (the dimension of the reaction area P2) is set in response to a speed at which the wafer W on the turntable 2 passes through the reaction area P2. As described later, because the plasma of the ammonia gas fills the reaction area P2, the entire surface of the wafer W is evenly provided with the plasma process.

Referring to FIGS. 4, 5, and 6, a Faraday shield 95 is arranged between the casing 90 and the antenna 83. The Faraday shield 95 prevents an electric field component of an electromagnetic field generated by the antenna from downward directing and causes a magnetic field component of the electromagnetic field to downward pass through. The Faraday shield 95 is formed to be substantially a box and has an opening on an upper side. The Faraday shield 95 is made of a metallic plate (a conductive plate) which is a conductive plate-like body and is grounded in order to cut off the electric field. The slits 97 forming rectangular openings in the metallic plate are provided in a bottom surface of the Faraday shield 95 to cause the magnetic field to pass through the Faraday shield 95.

Each slit 97 does not communicate with other slits 97 adjacent to the slit 97. Said differently, a metallic plate forming the Faraday shield 95 is positioned along the peripheral direction and around the slits 97. The slits 97 are formed in a direction perpendicular to the direction of the antenna 83 and are arranged at multiple positions at an even interval along the length direction of the antenna 83 and below the antenna 83. The slits 97 are not formed at a position corresponding to the upper side of the plasma generating gas nozzle 32. Therefore, the ammonia gas is prevented from changing to the plasma inside the plasma generating gas nozzle 32.

Referring to FIGS. 5 and 6, the slits 97 are formed at positions lower than the portions of the antenna 83 (the linear portion 83a and the opposite portion 83b) extending linearly from the center to the outer periphery of the turntable 2. Meanwhile, the slits 97 are not formed on a side lower than the above portions. Specifically, the slits 97 are not formed in an area corresponding to the portions of the antenna 83 provided between the linear portion 83a and the opposite portion 83b and extending substantially in a tangential direction of the turntable 2 and an area corresponding to a curved portion of the antenna 83 provided between ends of the linear portion 83a and the opposite portion 83b.

Said differently, when the slits 97 are formed thoroughly along the antenna 83, the slits 97 should be arranged at different angles at curved portions of the antenna 83. However, in this case, adjacent slits 97 corresponding to the curved portion of the antenna 83 may be connected each other. Then, an effect of cutting off the electric field becomes small. If the widths of the slits 97 are reduced to prevent the adjacent slits 97 from connecting, the amount of the magnetic field component such as the strength of the magnetic field in the curved portion reaching the wafer W becomes weaker than that in the linear portion 83a and the opposite portion 83b. Further, if the distance between the adjacent slits 97 on the area corresponding to the outside of the antenna 83 is made longer, not only the magnetic field but also the electric field reaches the wafer W to thereby possibly give a charging damage to the wafer W.

Within the embodiment, in order to set the amount of the magnetic field component such as the strength of the magnetic field reaching the wafer W from the antenna 83 through the slits 97 to be identical, the linear portion 83a is arranged to cover a position where the wafer W passes and the slits 97 are formed on a side lower that the linear portion 83a. On the side lower than the curved portion extending from the ends of the linear portion 83a, the slits 97 are not formed and the conductive plate forming the Faraday shield 95 is arranged to cut off not only the electric field component but also the magnetic field component. Therefore, as described later, the amount of the plasma generated along the radius direction of the turntable 2 is uniformized.

Therefore, when the slits 97 are viewed at an arbitrary position, opening widths of the slits 97 are set to be identical in the longitudinal directions of the slits 97. The opening widths of all the slits 97 in the Faraday shield 95 are adjusted to be the same. Said differently, the slits 97 are structured to set groove-like longitudinal openings at multiple positions so that the groove-like longitudinal openings are arranged in parallel and perpendicular to the linear portion 83a and the opposite portion 83b of the antenna 83 between a position apart on the upstream side in the rotational direction of the turntable 2 from the linear portion 83a to a position apart on the downstream side in the rotational direction of the turntable 2 from the opposite portion 83b. Between the linear portion 83a and the opposite portion 83b, multiple reinforcing ribs (band-like conductors) are provided between the openings (the slits 97) and arranged along the linear portion 83a or the opposite portion 83b.

An insulating member 94 (see FIG. 4) made of, for example, quartz is interposed between the Faraday shield 95 and the antenna 83 in order to insulate the Faraday shield 95 from the antenna 83. The insulating member 94 is substantially shaped like a box and has an opening on the side of the upper surface of the insulating member 94. Referring to FIG. 7, the Faraday shield 95 is omitted from illustration in order to explain a positional relationship between the antenna 83 and the wafer W. Except for FIG. 4, the insulating member 94 is omitted from illustration.

A side ring 100 in an annular shape is arranged at a position slightly lower than the turntable 2 on the outer peripheral side of the turntable 2. Evacuation ports 61 and 62 are formed at two positions on the upper surface of the side ring 100 so as to be mutually separated in the peripheral direction of the side ring 100. These two evacuation ports 61, 62 include a first evacuation port 61 and a second evacuation port 62. The first evacuation port 61 is positioned on a side closer to the separation area D that is positioned on the downstream side of the turntable 2 relative to the first processing gas nozzle 31 in the rotational direction of the turntable 2 between the first processing gas nozzle 31 and the separation area D. The second evacuation port 62 is positioned on a side closer to the separation area D between the plasma generating gas nozzle 32 and the separation area D positioned on the downstream side of the plasma generating gas nozzle 32 in the rotational direction of the turntable 2. Therefore, the second evacuation port 62 is positioned in the vicinity of an apex of a triangle formed by connecting a point of the rotational center of the turntable 2, a point where the edge of wall portion 92 on the side of the reaction area P2 intersect the outer peripheral edge of the turntable 2, and this apex.

The first evacuation port 61 is provided to evacuate the process gas and the separation gas. The second evacuation port 62 is provided to evacuate the plasma generating gas and the separation gas. The upper surface of the side ring 100 has a gas flow path 101 in a groove-like shape on the outer edge side of the casing 90. The gas flow path 101 is provided to flow the gas into the second evacuation port 62 and to prevent the gas from flowing into the casing 90. The first and second evacuation ports 61 and 62 may be connected to an evacuating mechanism such as a vacuum pump 64 through evacuation pipes 63 provided with a pressure controller 65 such as a butterfly valve.

Referring to FIG. 1, a protruding portion 5 is provided at a center portion on the lower surface of the ceiling plate 1 and protrudes on a side lower than the ceiling plate. The protruding portion 5 prevents the process gas from being mixed with the plasma generating gas in the center area C. Said differently, the protruding portion 5 includes a wall portion vertically extending from the side of the turntable 2 to the side of the ceiling plate 11 and the peripheral direction and a wall portion vertically extending from the side of the ceiling plate 11 to the side of the turntable 2 and the peripheral direction. These wall portions are alternately arranged in a radius direction of the turntable 2.

Referring to FIGS. 2 to 4, the transfer opening 15 is formed in the side wall of the vacuum chamber 1. The transfer opening 15 is provided to serve or receive the wafer W between a transfer arm (not illustrated) and the turntable 2. The transfer opening 15 can be hermetically opened or closed using a gate valve G. Further, a lift pin (not illustrated) for lifting the wafer W from the back surface side of the wafer through a through hole formed in the turntable 2 is provided on the lower side of the turntable 2 at a position corresponding to the transfer opening 15.

The film forming deposition apparatus includes a control unit 120 having a computer for controlling entire operations of the plasma processing apparatus as illustrated in FIG. 1. A program for performing a film deposition process described below is stored in a memory of the control part 120. The program is made to perform steps of the following operations of the plasma processing apparatus. The program is installed in the control unit 120 from a memory unit 121 being a recording medium such as a hard disk, a compact disk, a magneto-optical disk, a memory card, and a flexible disk.

Next, functions of the above embodiment are described. At first, the gate valve G is released. While the turntable 2 is intermittently rotated, for example, five wafers W are mounted onto the turntable 2 by the transfer arm (not illustrated) through the transfer opening 15. Subsequently, the gate valve G is closed. The inside of the vacuum chamber 1 is completely evacuated by the vacuum pump 64, and simultaneously the turntable 2 is rotated at, for example, 2 rpm to 240 rpm in the clockwise direction. Then, the wafer W is heated to, for example, about 300° C. by the heater unit 7.

Subsequently, a DCS gas is discharged from the process gas nozzle 31, and simultaneously an ammonia gas is discharged from the plasma generating gas nozzle 32 so that the pressure in the reaction area P2 has a positive pressure than areas inside the vacuum chamber 1 other than the reaction area P2 inside the vacuum chamber 1. Further, a separation gas is discharged from the separation gas nozzles 41 and 42, and a nitrogen gas is discharged from the separation gas supplying tube 51 and purge gas supplying pipes 72 and 73. The inside of the vacuum chamber 1 is adjusted to have a predetermined processing pressure by the pressure controller 65. Further, high frequency power is supplied to the antenna 83.

In the adsorption area P1, a component of the DCS gas adsorbs onto the surface of the wafer W thereby producing an adsorption layer. When the wafer W passes through the adsorption area P1, a movement speed is faster on the side of the outer periphery of the turntable 2 than on the side of the center of the turntable 2 when the wafer W passes through the adsorption area P1. Therefore, the film thickness on the side of the outer periphery of the turntable 2 is apt to become thinner than the film thickness on the side of the center of the turntable 2. However, because the component of the DCS gas is quickly adsorbed, the adsorption layer is uniformly formed through the surface of the wafer when the wafer W passes through the adsorption area P1.

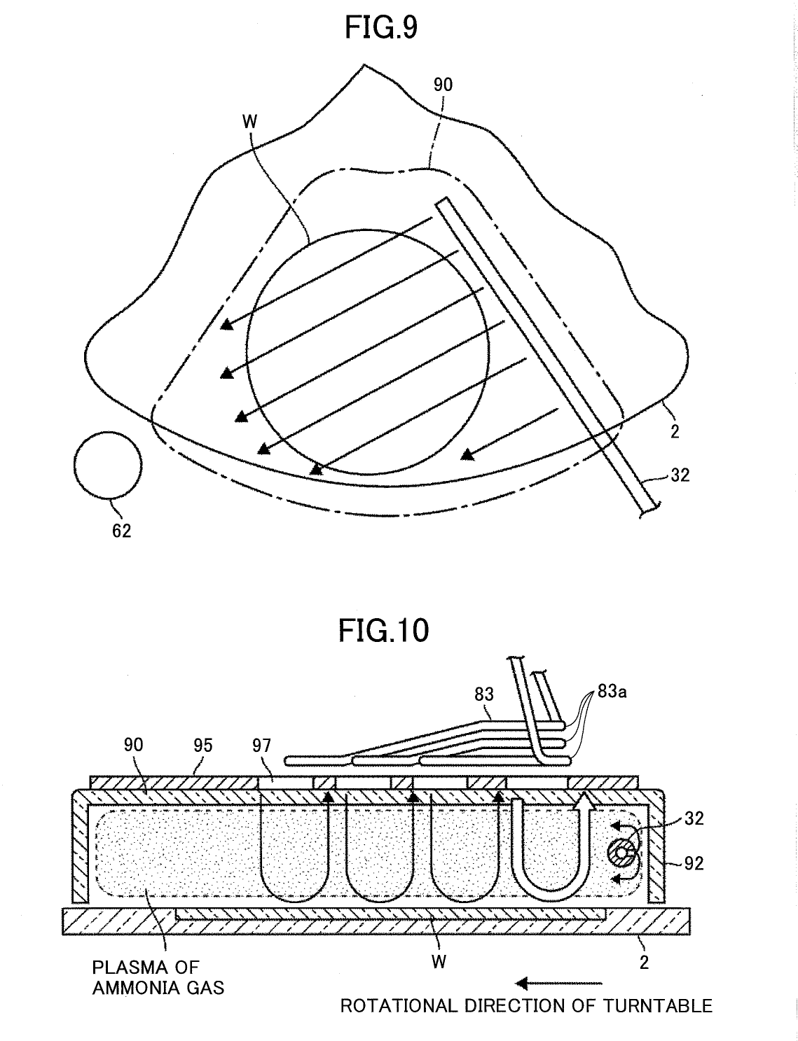

Because the position of the second evacuation port 62 is set in the reaction area P2, the ammonia gas discharged from the plasma generating gas nozzle 32 collides against the wall portion 92 on the upstream side in the rotational direction of the turntable 2, and thereafter linearly flows toward the second evacuation port 62 as illustrated in FIG. 9. While the ammonia gas flows toward the second evacuation port 62, the ammonia gas is quickly changed by the magnetic field to the plasma on the side lower than the three stages of the linear portions 83a of the antenna 83 as illustrated in FIG. 10. Because the opening widths of the slits 97 are identical in the radius direction of the turntable 2, the amounts (the densities) of the generated plasma corresponding to the slits 97 are identical along the radius direction. Thus, the plasma flows toward the second evacuation port 62.

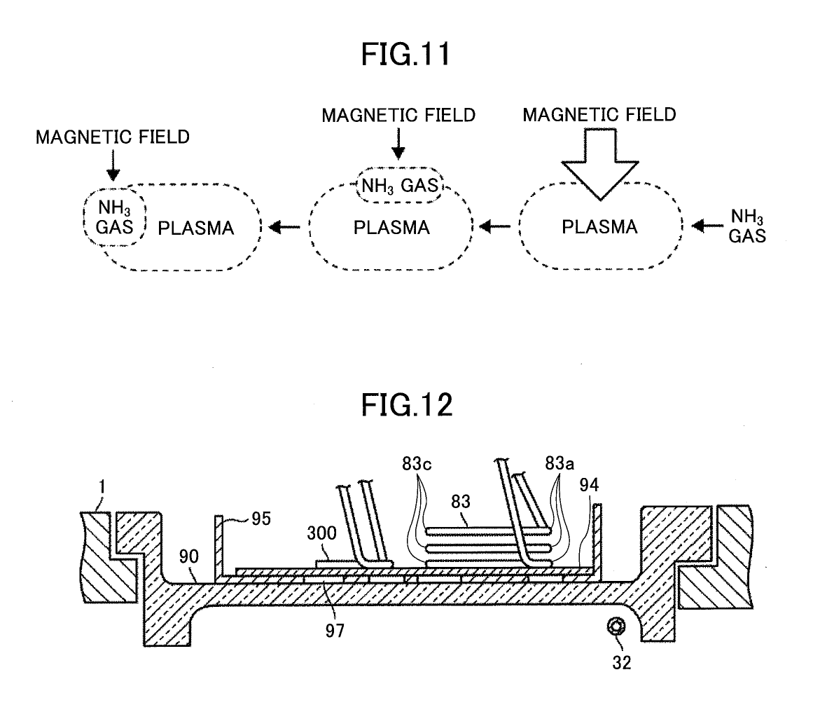

When the ammonia radical is inactivated by the collision against the wafer W or the like and changed back to the ammonia gas, the ammonia radical is changed to the plasma again by the magnetic field generated by the opposite portion 83b which is arranged on the side of the second evacuation port 62 relative to the linear portion 83a. Referring to FIG. 11, because the pressure inside the reaction area P2 is set higher than the pressure inside the areas inside the vacuum chamber 1 other than the reaction area P2, the plasma of the ammonia gas fills the reaction area P2.

Further, since the dimension of the reaction area P2 is set as described above, times while the plasma is supplied to the wafer W on the turntable 2 become identical along the radius direction of the turntable 2. When the wafer W passes through the reaction area P2, the adsorption layer on the wafer W is uniformly nitrided through the surface of the wafer W and a reaction layer (a silicon nitride film) is formed. As described, as the wafers W alternately pass through the adsorption area P1 and the reaction area P2 by the rotation of the turntable, the multiple reaction layers are laminated to thereby form the thin film.

Since the gas flow path 101 is formed on the side ring 100 on the side of the outer periphery of the casing 90, the gases are evacuated through the gas flow path 101 and prevents from passing through the casing 90 while the above sequential processes are performed. Further, since the wall portion 92 is provided at the peripheral edge on the lower side of the casing 90, the nitrogen gas is prevented from intruding inside the casing 90.

Further, since the nitrogen gas is supplied between the adsorption area P1 and the reaction area P2, the process gas and the plasma generating gas (the plasma) is evacuated without mutually mixing. Further, because the purge gas is supplied on the lower side of the turntable 2, the gas dispersing toward the lower side of the turntable 2 is pushed back toward the first and second evacuation ports 61 and 62 by the purge gas. Further, since the separation gas is supplied to the center area C, mixture of the process gas and the plasma generating gas or the plasma is prevented inside the center area C.

Within the embodiment, the plasma generating gas nozzle 32 is linearly arranged between the side of the center of the turntable 2 and the side of the outer edge of the turntable 3, and the linear portions 83a of the antenna 83 are provided along the direction of the length of the plasma generating gas nozzle 32. The Faraday shield 95 formed with the slits 97 is arranged between the antenna 83 and the plasma generating gas nozzle 32. The slits 97 are not formed on the side lower than the portions extending from the both ends of the linear portions 83a and curving and are formed only in the portion corresponding to the linear portions 83a. Since the shapes of the slits 97 are identical, the amounts of the magnetic fields respectively passing through the slits 97 are identical. Therefore, a high uniformity is obtainable through the surface of the wafer W in the plasma process.

Further, the wall portion 92 is formed at the peripheral edges on the side of the lower surface of the casing 90 and through the peripheral direction, and simultaneously the discharge amount of the ammonia gas in the reaction area P2 surrounded by the wall portion 92 is adjusted to be higher than the areas of the vacuum chamber 1 other than the reaction area P2. Further, the plasma generating gas nozzle 32 is arranged inside the reaction area P2 on the upstream side of the rotational direction of the turntable 2, and simultaneously the discharge ports 33 of the plasma generating gas nozzle 32 are formed to face the wall portion 92 on the upstream side of the rotational direction. Therefore, since it is possible to prevent the nitrogen gas from intruding into the reaction area P2, it is possible to maintain a contact area between the wafer W and the plasma to be wide through the reaction area P2.

Further, a layout of the reaction area P2 is adjusted so that a speed difference caused between the rotational speed of the turntable 2 on the inner peripheral side and the rotational speed of the turntable 2 on the outer peripheral side is solved. As described above, since the amount of the plasma is uniformized through the radius direction of the turntable 2 and a contact time while the plasma contacts the wafer W is uniformized, the uniform plasma process can be performed through the surface of the wafer W. Said differently, since the DCS gas quickly adsorbs onto the wafer W as described above, the adsorption layer is uniformly formed through the surface of the wafer W. On the other hand, the plasma of the ammonia gas does not have a high reactivity when the adsorption layer is reacted. Therefore, by uniformizing the density of the plasma and the contact time while the plasma contacts the wafer, the film thickness of the reaction product can be uniformized through the surface of the wafer W.

Further, the linear portions 83a are laminated in the vertical direction, and the opposite portions 83b are arranged in the horizontal direction. Therefore, the plasma of the ammonia gas is quickly generated at the position lower than the linear portion 83a. Meanwhile, the ammonia gas generated when the plasma is inactivated is again changed to the plasma on the side lower than the opposite portion 83b. As described above, it is possible to widely maintain the plasma in the reaction area P2. When the ammonia gas is changed again to the plasma, the opposite portions 83b are arranged for the magnetic field component necessary for changing to the plasma. However, the opposite portions 83b are not excessively provided. Further, the linear portion 83a and the opposite portion 83b are connected in common to the high frequency power source 85. It is possible to perform a process with the high uniformity while restricting the cost of the plasma processing apparatus from increasing.

Further, since the slits 97 are not formed on the upper side of the plasma generating gas nozzle 32, it is possible to restrict an extraneous matter such as the reaction product from attaching to the inside or the outer wall of the plasma generating gas nozzle 32.

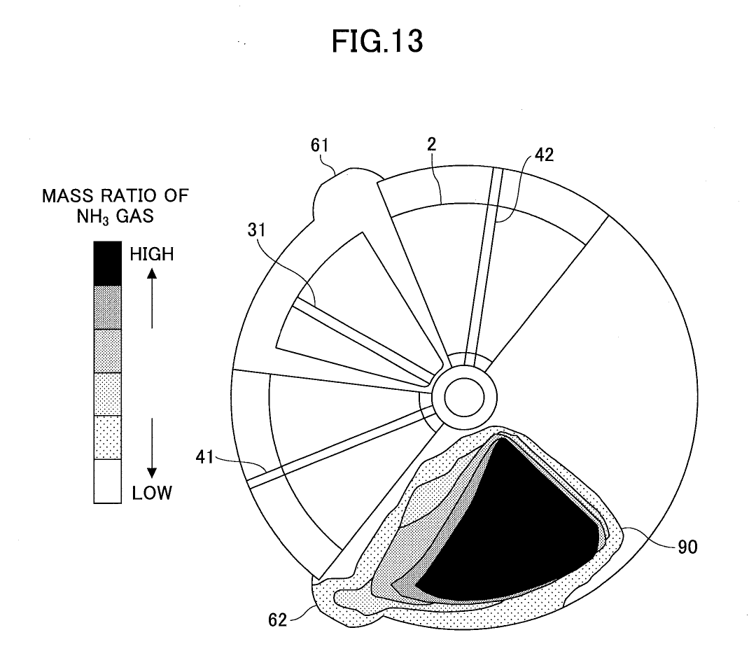

FIG. 12 illustrates another embodiment of the present invention. Said differently, the opposite portions 83b may be laminated in the vertical direction. Alternatively, an auxiliary antenna 300 that changes the ammonia gas generated when the plasma is inactivated again to the plasma may be provided on the downstream side in the rotational direction of the turntable 2 relative to the antenna 83 in addition to the antenna including the linear portions 83a and the opposite portions 83b. The auxiliary antenna 300 may be connected to the high frequency power source 85 for the antenna 83 or another high frequency power source different from the high frequency power source 85.

FIG. 13 illustrates a result of a simulation of a distribution of the ammonia gas on the lower side of the casing 90. Referring to FIG. 13, the ammonia gas supplied from the plasma generating gas nozzle 32 to the reaction area P2 flows toward the second evacuation port 62 while diffusing inside the reaction area P2. Therefore, the ammonia gas (the plasma) can be diffused through the reaction area P2 by arranging the second evacuation port 62 on the downstream side in the rotational direction of the turntable 2 relative to the casing 90 and outside the turntable 2.

Although not only the linear portions 83a but also the opposite portions 83b are linearly arranged in FIG. 6 illustrated above, the opposite portions 83b may be arranged in a curved shape so that the antenna 83 is shaped in a semicircle in its plan view. The slits 97 may be arranged along the length direction of the opposite portions 83b. Said differently, within the embodiment of the present invention, it is sufficient to linearly arrange the antenna 83 at a portion corresponding to the area where the wafer W passes and in the vicinity of the plasma generating gas nozzle3 32. Therefore, the other portions (the opposite portions 83b and the curved portions 83c) of the antenna 83 may be shaped like a curved line. Further, the slits 97 may be formed for the curved portions 83c in the vicinity of the opposite portion 83b. Within the embodiment of the present invention, “the curved portion 83a without the slit 97” is defined as a portion of the antenna 83 extending from the ends of the linear portion and area and curved. Within the previous embodiment, the curved portions 83c are wound by three times in the vertical direction. Instead of winding the antenna 83 around the vertical axis to form the three stages, the antenna 83 may be formed by winging by only one stage.

Further, instead of the plasma generating gas nozzle 32 of a gas injector type, a substantially box-like body having an opening on its lower surface side and extending along the radius direction of the turntable 2 may be provided inside the vacuum chamber 1 and the gas discharge ports 33 may be formed in the length direction of the substantially box-like body.

The type of the film deposited using the plasma processing apparatus described above is a silicon oxide (SiO₂) film, a titanium nitride (TiN) film, or the like instead of the silicon nitride film. In a case where the silicon oxide film is deposited, the plasma generating gas is, for example, oxygen (O₂) gas. In a case where the titanium nitride film is deposited, the adsorption gas and the plasma generating gas are an organic gas containing titanium and ammonia gas containing titanium, respectively. The present invention is applicable to the film deposition of the reaction product made of a nitride, an oxide, or a hydride in addition to the silicon nitride film and the titanium nitride film. The plasma generating gases used to deposit films of the nitride, the oxide, or the hydride are ammonia gas, oxygen gas, and hydrogen (H₂) gas, respectively.

The plasma generating gas nozzle 32 and the casing 90 described above may be arranged at a position on the downstream side in the rotational direction of the turntable 2 relative to the adsorption area P1 and on the upstream side in the rotational direction of the turntable 2 relative to the reaction area P2 and another plasma process may be performed at the position. In the other plasma process, an argon (Ar) gas is used as the plasma generating gas to perform a plasma altering process for the reaction product produced on the wafer W. The plasma altering process may be performed every lamination of one layer of multiple layers of the reaction product. Said differently, the plasma altering process may be performed every rotation of multiple rotations of the turntable 2.

Within the embodiment of the present invention, nozzle portions for supplying the plasma generating gas into the vacuum chamber are linearly arranged, and the linear portions of the antenna for generating the electromagnetic field (the electric field and the magnetic field) are formed along the length directions of the nozzle portions. Further, the Faraday shield is arranged between the antenna and the nozzle portions, the slits are formed in the Faraday shield at positions facing the linear portion, and the electric field of the electromagnetic field generated by the antenna is cut off to cause the magnetic field to pass therethrough. Meanwhile, the slits are not formed at positions facing the portions curving from both ends of the linear portions to cut off not only the electric field but also the magnetic field. The shapes of the slits are set to be identical. Therefore, the amounts of the magnetic field reaching the inside of the vacuum chamber can be uniformized along the length directions of the nozzle portions. Therefore, a high uniformity is obtainable in processing the surface of the substrate.

All examples and conditional language recited herein are intended for pedagogical purposes to aid the reader in understanding the embodiments and the concepts contributed by the inventor to furthering the art, and are to be construed as being without limitation to such specifically recited examples and conditions, nor does the organization of such examples in the specification relate to a showing of superiority or inferiority of the embodiments. Although the plasma processing apparatus has been described in detail, it should be understood that the various changes, substitutions, and alterations could be made hereto without departing from the spirit and scope of the invention.

What is claimed is:

1. A plasma processing apparatus performing a plasma process for a substrate inside a vacuum chamber, the plasma processing apparatus comprising:
a turntable for orbitally revolving a substrate mounting area, on which a substrate is mounted;
a nozzle portion that faces the substrate mounting area and has gas discharge ports for discharging a gas for generating plasma linearly arranged from a side of an outer periphery to a side of a center portion;
an antenna that includes a linear portion extending so as to cover a substrate passage area on a downstream side in a rotational direction of the turntable relative to the nozzle portion and a separated portion positioned separated from the linear portion in a plan view of the antenna, the antenna unit being wound around an axis vertically extending in up and down directions, and generates induction plasma in a process area to which the gas is supplied;
a Faraday shield including
a conductive plate provided between the antenna and the process area so as to be hermetically separated from the process area and to cut off an electric field of an electromagnetic field, and
a group of slits formed so as to orthogonally cross the antenna and cause a magnetic field of the electromagnetic field to pass through the slits,
wherein the group of slits is formed on at least a side lower than the linear portion, and a portion of the conductive plate without the group of slits is positioned on a side lower than a curved portion, at which the antenna curves from an end of the linear portion.

2. The plasma processing apparatus according to claim 1,
wherein a portion of the Faraday shield corresponding to the separated area of the antenna is arranged on a downstream side in the rotational direction of the turntable relative to the linear portion of the antenna.

3. The plasma processing apparatus according to claim 1,
wherein the antenna includes another linear portion positioned on a side opposite to the linear portion relative to the nozzle portion, and
the group of the slits is arranged on the side lower than the another linear portion.

4. The plasma processing apparatus according to claim 1,
wherein the antenna is wound around the axis by a plurality of turns,
wherein the linear portion positioned close to the nozzle portion is laminated by a plurality of stages.

5. The plasma processing apparatus according to claim 1,
wherein the antenna is wound around the axis by a plurality of turns,
wherein the portion of the Faraday shield corresponding to the separated area of the antenna is arranged on a downstream side of the rotational direction of the turntable relative to the linear portion, and
one turn and another turns of the plurality of turns of the antenna are arranged so as to shift each other along the rotational direction of the turntable.

6. The plasma processing apparatus according to claim 1, further comprising:
a wall portion that separates the process area in a shape of sector having side portions along two lines radially extending from a center of the turntable and separated in a peripheral direction of the turntable and downward extends from a ceiling plate of the vacuum chamber,
wherein the nozzle portion extends along the wall portion in the vicinity of the wall portion positioned on an upstream side of the process area.

7. The plasma processing apparatus according to claim 6,
wherein the wall portion is arranged so that VI/VO equals to LI/LO where VI designates a speed of an end of the substrate on a side of a rotational center on the turntable, VO designates a speed of an end of the substrate on a side of a periphery on the turntable, and LI and LO respectively designate lengths of the process area through which the end of the substrate on the side of the rotational center and the end of the substrate on the side of the periphery.

8. A method of performing a plasma process plasma for a substrate positioned inside a vacuum chamber, the plasma method comprising:
orbitally revolving a substrate by rotating a turntable after the substrate is mounted on a mounting area provided on the turntable;
supplying a gas for generating plasma from a nozzle portion that faces the turntable and linearly extends from a side of an outer periphery to a side of a center portion into a process area provided inside the vacuum chamber;
generating induction plasma in the process area by an antenna that includes a linear portion extending so as to cover a substrate passage area on a downstream side in a rotational direction of the turntable relative to the nozzle portion and a separated portion positioned separated from the linear portion in a plan view of the antenna, is wound around an axis vertically extending in up and down directions, and generates induction plasma in the process area to which the gas is supplied;
cutting off an electric field of an electromagnetic field that is generated by the antenna using a conductive plate provided between the antenna and the process area so as to hermetically separated from the process area; and
causing a magnetic field of the electromagnetic field to pass through a group of slits formed so as to orthogonally cross the antenna,
wherein the group of slits is formed on at least a side lower than the linear portion and a portion of the conductive plate without the group of slits is positioned on a side lower than a curved portion, at which the antenna curves from an end of the linear portion.
